(19) United States
(12) Patent Application Publication
(10) Pub. No.: US 2006/0087040 A1
(43) Pub. Date: Apr. 27, 2006

(54) Semiconductor device and method of manufacturing the same

(76) Inventor: Masao Shibasaki, Chino (JP)

Correspondence Address: HARNESS, DICKEY & PIERCE, P.L.C., P.O. BOX 828, BLOOMFIELD HILLS, MI, 48303, US

(21) Appl. No.: 11/233,282

(22) Filed: Sep. 22, 2005

(30) Foreign Application Priority Data
Oct. 25, 2004 (JP) 2004-309420

(51) Int. Cl. H01L 23/52

(52) U.S. Cl. 257/758

(57) ABSTRACT

A semiconductor device includes: an insulating film formed above a semiconductor substrate; a pad formed on the insulating film; a passivation film formed on the insulating film and the pad, the passivation film being provided with a first opening positioned on the pad; a first bulge member formed on the passivation film; a first insulating layer formed on the passivation film and the first bulge member, the first insulating layer being provided with a second opening positioned on the first opening; and rewiring formed on the first insulating layer and connected to the pad via the first opening and second opening.

### BACKGROUND OF THE INVENTION

1. Technical Field

The present invention relates to a semiconductor device and a method of manufacturing the semiconductor device. And, in particular, the invention relates to a semiconductor device, in which separation of a passivation film from an insulating layer deposited thereon is restrained, and a method of manufacturing the semiconductor device. Further, the invention relates to a semiconductor device, in which separation of an insulating layer provided with rewiring from an insulating layer covering the rewiring is restrained, and a method of manufacturing the semiconductor device.

2. Related Art

FIG. 6 is a cross-sectional view showing a semiconductor device of the related art. Wafer Level Chip Size Package (WLCSP) is applied to this semiconductor device. In detail, a transistor (not shown) is formed on a silicon substrate 101. On the transistor, there is formed a multi-layered wiring layer 110. On the upper most layer of the wiring layer, there are formed Al alloy pads 121. The multi-layered wiring layer 110 is covered with a passivation film 122. The passivation film 122 is provided with openings positioned on the Al alloy pads 121. On the passivation film 122, a polyimide resin layer 124 and rewiring 125 are deposited in this order. The polyimide resin layer 124 is provided with openings positioned on the Al alloy pads 121. The rewiring 125 is partially embedded in the openings to be connected to the Al alloy pads 121.

On the rewiring 125, there is formed a solder resist layer 127. The solder resist layer 127 is provided with openings each positioned on a part of the rewiring 125. In each of the openings, there is embedded a solder ball 128. The solder balls 128, terminals for connecting to the outside, are thus provided at different positions from the Al alloy pads 121 in the planar layout. This structure is formed on a wafer of the silicon substrate 101, and then separated into a discrete chip of semiconductor device by separating the silicon substrate 101 and the upper layers thereof along a dicing line 101a. See, Japanese Unexamined Patent Publication No. 2001-144217 (FIG. 7), for example.

The passivation film is often formed of a silicon nitride film or a multi-layered film composed of a silicon nitride film and silicon oxide film. Accordingly, stresses are easily caused between the polyimide layer and the passivation film. When stresses are caused, there is a possibility that the polyimide layer is separated from the passivation film to separate the rewiring from the pads.

By the same action, the solder resist layer is separated from the polyimide layer, and as a result, it is possible that the solder balls are separated from the rewiring.

### SUMMARY

In view of the above circumstances, an advantage of the invention is to provide a semiconductor device, in which separation of the passivation film from the insulating layer deposited thereon is restrained, and a method of manufacturing the semiconductor device. Further, another advantage of the invention is to provide a semiconductor device, in which separation of an insulating layer provided with rewiring from an insulating layer covering the rewiring is restrained, and a method of manufacturing the semiconductor device.

In view of the above technical problems, a semiconductor device according to an aspect of the invention includes, a pad formed on the insulating film, a passivation film formed on the insulating film and the pad, the passivation film being provided with a first opening positioned on the pad, a first bulge member formed on the passivation film, a first insulating layer formed on the passivation film and the first bulge member, the first insulating layer being provided with a second opening positioned on the first opening, and rewiring formed on the first insulating layer and connected to the pad via the first opening and second opening.

According to the semiconductor device, the first bulge member is formed on the passivation film. Therefore, the first bulge member, with an anchor effect, wards off stresses acting on the interface between the passivation film and the first insulating layer, thus making it hard to separate the passivation film from the first insulating layer.

The first bulge member is preferably made of metal. In this case, the adhesiveness of the passivation film with the first bulge member can be made higher than the adhesiveness of the passivation film with the first insulating layer (e.g., polyimide resin). In this case, the first bulge member can be formed using metal paste.

The first bulge member is preferably formed in the periphery of the passivation film.

The semiconductor device can further include a second insulating layer formed on the first insulating layer and the rewiring, the second insulating layer being provided with a third opening positioned on the rewiring, and a connecting terminal embedded in the third opening and connected to the rewiring. The connecting terminal is, for example, a solder ball.

Further, a second bulge member formed on the first insulating layer and covered with the second insulating layer can further be included. In this case, the second bulge member, with an anchor effect, wards off stresses acting on the interface between the first insulating layer and the second insulating layer, thus making it hard to separate the first insulating layer from the second insulating layer.

The second bulge member can be made of the same material as the rewiring. In this case, the second bulge member and the rewiring can be formed in the same process.

Another semiconductor device according to another aspect of the invention includes, an insulating film formed above a semiconductor substrate, a pad formed on the insulating film, a passivation film formed on the insulating film and the pad, the passivation film being provided with a first opening positioned on the pad, a first insulating layer formed on the passivation film, the first insulating layer being provided with a second opening positioned on the first opening, rewiring formed on the first insulating layer and connected to the pad via the first opening and second opening, a bulge member formed on the first insulating layer, and a second insulating layer formed on the first insulating layer, the bulge member, and the rewiring.

A method of manufacturing a semiconductor device according to still another aspect of the invention includes the step of forming an insulating film above a semiconductor substrate, the step of forming a pad on the insulating film, the step of forming a passivation film on the insulating film and the pad, the step of providing a first opening to the passivation film, the first opening being positioned on the pad, the step of forming a first bulge member on the passivation film, the step of forming a first insulating layer on the passivation film and the first bulge member, the first insulating layer being provided with a second opening positioned on the first opening, and the step of forming rewiring connected to the pad via the first opening and the second opening on the first insulating layer.

The step of forming the first bulge member can further include step of ejecting metal paste on the passivation film using an inkjet mechanism, and the step of calcining metal paste on the passivation film to form the first bulge member. In this case, since the first bulge member can be formed without using a plasma process, no plasma damage is applied to the semiconductor device when forming the first bulge member.

In the method of manufacturing a semiconductor device, the step of forming the rewiring can include the step of forming a conductive layer on the first insulating layer, and the step of patterning the conductive layer to form the rewiring and a second bulge member. And the method of manufacturing a semiconductor device can further include, after the step of patterning the conductive layer to form the rewiring and the second bulge member, the step of forming a second insulating layer on the first insulating layer, the rewiring, and the second bulge member. The second insulating layer includes a third opening positioned on the rewiring. The method of manufacturing a semiconductor device can also include the step of forming a connecting terminal in the third opening.

The method of manufacturing a semiconductor device can also include, after the step of forming the rewiring, the step of forming the second bulge member on the first insulating layer, the step of forming a second insulating layer on the first insulating layer, the rewiring, and the second bulge member. The second insulating layer is provided with a third opening positioned on the rewiring. And the method of manufacturing a semiconductor device can further include the step of forming a connecting terminal in the third opening.

Another method of manufacturing a semiconductor device according to still another aspect of the invention includes the step of forming an insulating film above a semiconductor substrate, the step of forming a pad on the insulating film, the step of forming a passivation film on the insulating film and the pad, the step of providing a first opening to the passivation film, the first opening being positioned on the pad, the step of forming a first insulating layer on the passivation film, the first insulating layer being provided with a second opening positioned on the first opening, the step of forming, on the first insulating layer, a bulge member and rewiring connected to the pad via the first opening and the second opening, the step of forming a second insulating layer on the first insulating layer, the rewiring, and the bulge member. The second insulating layer is provided with a third opening positioned on the rewiring.

### BRIEF DESCRIPTION OF THE DRAWINGS

The invention will now be described with reference to the accompanying drawings, wherein like numbers refer to like elements, and wherein:

FIG. 1A is a cross-sectional view for explaining a method of manufacturing a semiconductor device according to a first embodiment of the invention. FIG. 1B is an enlarged view of a substantial part of FIG. 1A.

FIG. 2A is a cross-sectional view for explaining the subsequent process to the process shown in FIG. 1A. FIG. 2B is a cross-sectional view for explaining the subsequent process to the process shown in FIG. 2A. FIG. 2C is a cross-sectional view for explaining the subsequent process to the process shown in FIG. 2B.

FIG. 3A is a cross-sectional view for explaining the subsequent process to the process shown in FIG. 2C. FIG. 3B is a cross-sectional view for explaining the subsequent process to the process shown in FIG. 3A.

FIG. 4A is a plan view for explaining a first example of the planar shape of a first bulge member 23. FIG. 4B is a plan view for explaining a second example of the planar shape of the first bulge member 23. FIG. 4C is a plan view for explaining a third example of the planar shape of the first bulge member 23.

FIG. 5A is a cross-sectional view for explaining a method of manufacturing a semiconductor device according to a second embodiment of the invention. FIG. 5B is a cross-sectional view for explaining the subsequent process to the process shown in FIG. 5A. FIG. 5C is a cross-sectional view for explaining the subsequent process to the process shown in FIG. 5B.

FIG. 6 is a cross-sectional view of a semiconductor device of the related art.

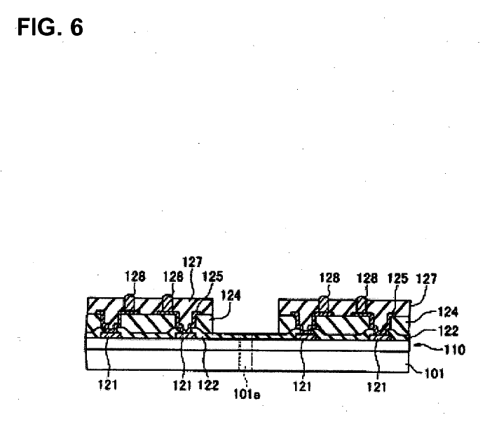

### DESCRIPTION OF THE EMBODIMENTS

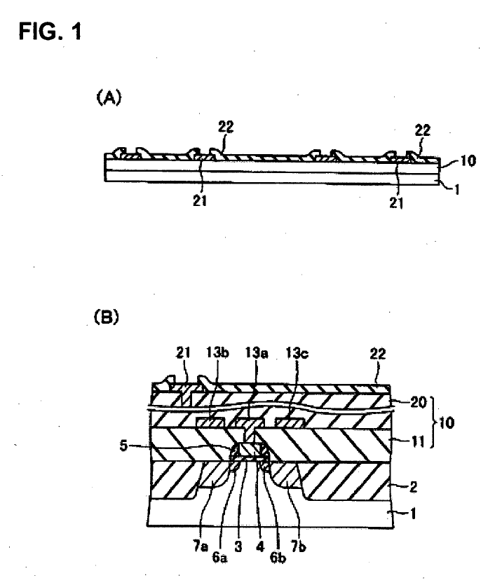

Hereinafter, embodiments of the present invention are described with reference to the accompanying drawings. Each of FIGS. 1A, 2A through 2C, 3A, and 3B is a cross-sectional view for explaining the method of manufacturing the semiconductor device according to the first embodiment. FIG. 1B is an enlarged view of the silicon substrate and the wiring layer shown in FIG. 1A. In the present embodiment, a number of semiconductor devices are formed on a wafer of a silicon substrate 1, and then the silicon substrate 1 is divided into a number of chips.

Firstly, as illustrated in the enlarged view of the substantial section shown in FIG. 1B, an element separating film 2 is provided to the wafer of the silicon substrate 1 to separate a number of element areas from each other. Subsequently, a gate oxidizing film 3 is provided to each of the element areas by thermally-oxidizing the silicon substrate 1. Subsequently, a polysilicon film is formed on the whole surface including the surface of the gate oxidizing film 3, and then the polysilicon film is patterned. Thus, a gate electrode 4 can be formed on the gate oxidizing film 3.

Subsequently, impurities are introduced in the silicon substrate 1 using the gate electrodes 4 and the element separation layers 2 as masks. Thus, low concentration impurity regions 6a, 6b are provided to each of the element areas. Subsequently, a silicon oxide film is deposited on the whole surface including the surface of the gate electrode 4, and then the silicon oxide film is etched back. Thus, a sidewall 5 can be formed on the side surface of the gate electrode 4. Subsequently, impurities are introduced in the silicon substrate 1 using the gate electrodes 4, the element separation layers 2, and the sidewall 5 as masks. Thus, impurity regions 7a, 7b to form the source and the drain are provided to each of the element areas. Through the processes described above, a number of transistors as examples of the semiconductors are provided to the silicon substrate 1.

Subsequently, on the whole surface including the surfaces of the transistors, there is formed an interlayer insulating film 11 made of silicon oxide. And further subsequently, connecting holes (not shown) respectively positioned on the gate electrode 4, and the impurity regions 7a, 7b are provided to the interlayer insulating film 11. And subsequently, the Al alloy layer is formed on the interlayer insulating film 11 and also inside the connecting holes, and the Al alloy is then patterned. Thus, the interlayer insulating film 11 is provided with Al alloy wiring 13a connected to the gate electrode 4, and Al alloy wiring 13b, 13c respectively connected to the impurity regions 7a, 7b. Subsequently, the interlayer insulating films and the Al alloy wiring are repeatedly deposited on the Al alloy wiring 13a, 13b, and 13c. And then, the upper most interlayer insulating film 20 is formed. A multi-layered wiring layer 10 is thus formed.

Subsequently, as shown in FIGS. 1A and 1B, an Al alloy film is formed on the multi-layered wiring layer 10, and the Al alloy film is then patterned. Thus, a number of Al alloy wiring layers (not shown) and a number of Al alloy pads 21 are formed on the multi-layered wiring layer 10. The Al alloy pads 21 are connected to the Al alloy wiring layer (not shown), the lower layer, via the connecting holes provided to the interlayer insulating film 20.

Subsequently, a passivation film 22 made of silicon nitride is formed on the whole surface including the surfaces of the multi-layered wiring layer 10 and the Al alloy pads 21. Further subsequently, a resist pattern (not shown) is formed on the passivation film 22, and the passivation film 22 is then etched using the resist pattern as a mask. Thus, the passivation film 22 is provided with openings positioned on the Al alloy pads 21. After then, the resist pattern is removed.

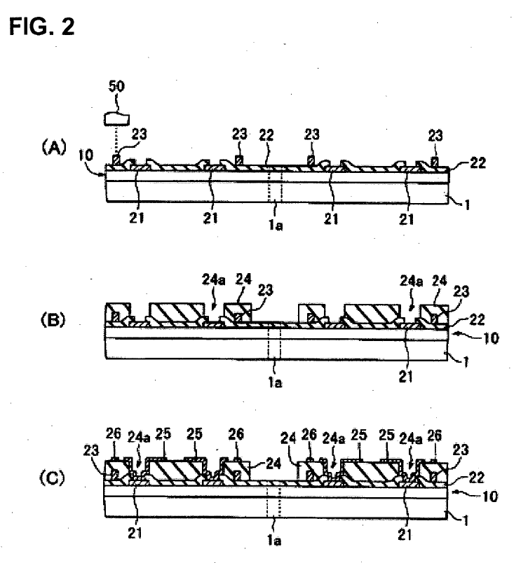

Subsequently, as shown in FIG. 2A, metal paste is ejected to a part of the passivation film 22 using an inkjet mechanism 50, and then the ejected metal paste is calcined. Thus, the first bulge members 23 are formed on the passivation film 22. The positions at which the first bulge members 23 are formed are preferably in the periphery of the passivation film 22 after divided into the discrete chips. The metal paste used in the process is made by dispersing particles of a metal such as Ag, Au, Al, Cu, TiW, or TiN in a medium. The diameters of the metallic particles are, for example, not larger than 20 nm. Further, the inkjet mechanism 50 is for ejecting the metal paste from a nozzle using, for example, a piezoelectric element, but those for ejecting the metal paste from a nozzle using a bubble-jet method can also be adopted.

Subsequently, as shown in FIG. 2B, a polyimide resin layer 24 is formed on the whole surface including the surface of passivation film 22 and the surface of the first bulge member 23 using a spin coat process. Further subsequently, a photoresist film (not shown) is coated on the polyimide resin layer 24, and then the photoresist film is exposed and then developed. Thus, the resist pattern is formed on the polyimide resin layer 24. The resist pattern is provided with openings above the openings of the passivation film 22. Subsequently, the polyimide resin layer 24 is etched using the resist pattern as a mask. Thus, the polyimide resin layer 24 is provided with openings 24a positioned on the Al alloy pads 21. In this case, the polyimide resin layer 24 positioned on the dicing line 1a is also removed. After then, the resist pattern is removed.

Note that, if the polyimide resin layer 24 is made of a photosensitive polyimide resin, formation of the openings 24a and removal of the polyimide resin layer 24 positioned on the dicing line 1a can be realized by directly exposing and then developing the polyimide resin layer 24 without providing the resist pattern on the polyimide resin layer 24.

Subsequently, as shown in FIG. 2C, a TiW layer is formed on the entire surface of the polyimide resin layer 24 including the openings 24a, and a Cu seed layer is formed on the TiW layer. And then, a Cu layer is formed on the Cu seed layer using a plating process.

Further subsequently, a photoresist film (not shown) is provided on the Cu layer, and then the photoresist film is exposed and then developed. Thus, a resist pattern is formed on the Cu layer. Subsequently, the Cu layer, the Cu seed layer, and the TiW layer are etched using the resist pattern as a mask. Thus, a rewiring 25 composed of the TiW layer, the Cu seed layer, and the Cu layer deposited thereon, and second bulge members 26 are formed on the polyimide resin layer 24. The rewiring 25 is partially embedded in the openings 24a to be connected to the Al alloy pads 21. The positions at which the second bulge members 26 are formed are preferably in the periphery of the polyimide resin layer 24 after divided into the discrete chips. After then, the resist pattern is removed.

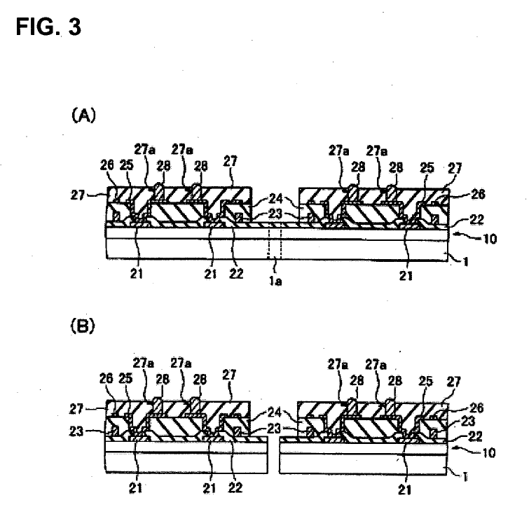

Subsequently, as shown in FIG. 3A, a solder resist layer 27 is formed on the entire surface including the rewiring 25 and the polyimide resin layer 24 using, for example, a spin coat process. And subsequently, the solder resist layer 27 is exposed and then developed. Thus, the solder resist layer 27 is provided with openings 27a each positioned on a part of the rewiring 25, and the solder resist layer 27 positioned on the dicing line 1a is removed.

Subsequently, solder balls 28 are disposed on the openings 27a, and then reflowed. Thus, the solder balls 28 are connected to the rewiring 25 to function as terminals to be connected to a mounting board (not shown).

Subsequently, as shown in FIG. 3B, the semiconductor device is divided along the dicing line 1a into the discrete chips. In the divided semiconductor device, the first bulge members 23 are positioned in the periphery of the semiconductor device. Further, the adhesiveness of the first bulge members 23 with the passivation film 22 is higher than the adhesiveness of the polylmide resin layer 24 with the passivation film 22. Therefore, the first bulge member 23 can ward off the stresses acting on the interface between the passivation film 22 and the polyimide resin layer 24, thus preventing separation of the passivation film 22 from the polyimide resin layer 24.

Further, the adhesiveness of the second bulge members 26 with the polyimide resin layer 24 is higher than the adhesiveness of the solder resist layer 27 with the polyimide resin layer 24. Therefore, the second bulge members 26 can ward off the stresses acting on the interface between the polyimide resin layer 24 and the solder resist layer 27, thus preventing separation of the polyimide resin layer 24 from the solder resist layer 27.

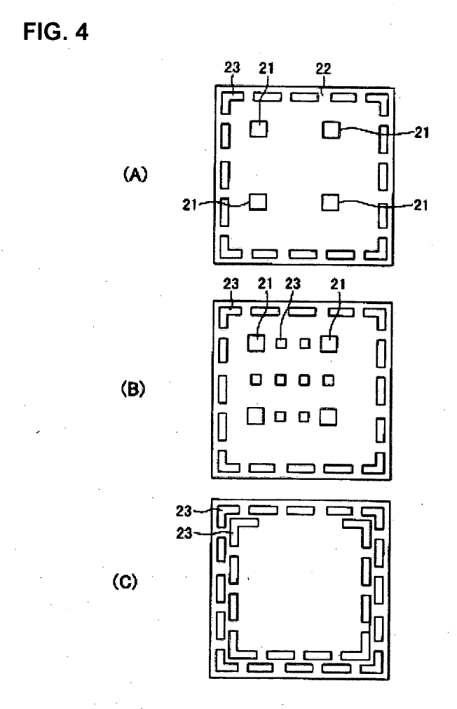

FIG. 4A is a plan view for explaining a first example of the planar shapes of the first bulge members 23. In the present example, the first bulge members 23 are formed like stitches along the periphery of the passivation film 22 after divided into the chips. Further, in each of the corners of the chips, the first bulge member 23 is substantially L-shaped.

FIG. 4B is a plan view for explaining a second example of the planar shapes of the first bulge members 23. In the present example, a number of the first bulge members 23 are provided between the Al alloy pads 21 in addition to the positions shown in FIG. 4A. In this case, the polyimide resin layer 24 and the solder resist layer 27 are harder to be separated from each other than the case of the first example.

FIG. 4C is a plan view for explaining a third example of the planar shapes of the first bulge members 23. In the present example, the first bulge members 23 are formed like a double line along the periphery of the passivation film 22 after divided into the chips. In each of the double line, the first bulge members 23 are shaped like stitches, but arranged so that a space between the stitches of one line does not overlap a space between the stitches of the other line. In this case, the polyimide resin layer 24 and the solder resist layer 27 are harder to be separated from each other than the case of the first example.

Note that the planar shapes of the second bulge members 26 can be the same as the first bulge members 23 shown in FIGS. 4A through 4C, or can be different therefrom.

As described above, according to the first embodiment of the invention, since the first bulge members 23 are formed on the passivation film 22, the stresses acting on the interface between the passivation film 22 and the polyimide resin layer 24 are warded off by the first bulge members 23, thus preventing separation of the passivation film 22 from the polyimide resin layer 24. Further, since the first bulge members 23 can be formed by ejecting the metal paste using the inkjet mechanism 50, a dry etching process can be eliminated. Therefore, no plasma damage is applied to the Al alloy pads 21 in forming the first bulge members 23.

Further, since the second bulge members 26 are formed on the polyimide resin layer 24, stresses acting on the interface between the polyimide resin layer 24 and the solder resist layer 27 are warded off by the second bulge members 26, thus preventing separation of the polyimide resin layer 24 from the solder resist layer 27. Further, since the second bulge members 26 and the rewiring 25 are formed in the same process, the number of processes can be prevented from increasing.

Note that the multi-layered wiring layer 10 does not need to be formed on the dicing line 1a. Such a configuration can be formed by, for example, removing the interlayer insulating films and the Al alloy films positioned on the dicing line 1a when providing the connecting holes to each of the interlayer insulating films and when patterning the Al alloy films to form the Al alloy wiring.

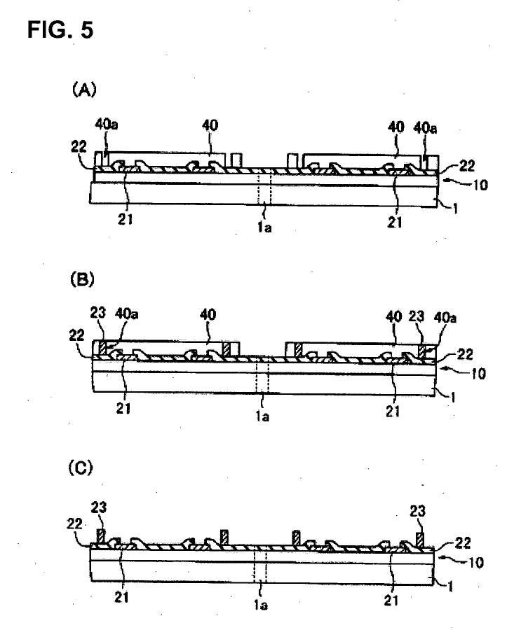

Each of FIGS. 5A through 5C is a cross-sectional view for explaining a method of manufacturing a semiconductor device according to a second embodiment of the invention. The present embodiment is the same as the first embodiment except the process of forming the first bulge members 23. Hereinafter, the same elements as those in the first embodiment are denoted with the same reference numerals, and all descriptions other than those for the process of forming the first bulge members 23 are omitted.

As shown in FIG. 5A, firstly a photoresist film is coated on the entire surface of the passivation film 22, and then the photoresist film is exposed and developed. Thus, a resist pattern 40 is formed on the passivation film 22. The resist pattern 40 is provided with openings 40a at positions to which the first bulge members 23 are to be provided.

Subsequently, as shown in FIG. 5B, the metal paste is embedded in the openings 40a using a squeegee, and then the metal paste in the openings 40a is calcined at, for example, 230° C. for one hour.

Subsequently, as shown in FIG. 5C, the resist pattern 40 is removed. Thus, the first bulge members 23 are formed.

According to the second embodiment, the same advantages as the first embodiment can be obtained. Further, since a number of the first bulge members 23 can be formed in the same process, productivity of the semiconductor device can be enhanced.

Note that the present invention is not limited to the embodiments described above, but can be modified in various manners to be practiced within a scope or spirit of the invention. For example, in the first and second embodiments, the second bulge members 26 can be formed by the same method as the method of forming the first bulge members 23. According to such a modification, the second bulge members 26 can be formed higher than the rewiring 25.

Further, the shape of each of the first bulge members 23 and the second bulge members 26 is not limited to the examples described above, but can be shaped like, for example, a lattice, a rhombus, a crisscross, or a slit.

What is claimed is:

1. A semiconductor device, comprising:
an insulating film formed above a semiconductor substrate;
a pad formed on the insulating film;
a passivation film formed on the insulating film and the pad, the passivation film being provided with a first opening positioned on the pad;
a first bulge member formed on the passivation film;
a first insulating layer formed on the passivation film and the first bulge member, the first insulating layer being provided with a second opening positioned on the first opening; and
rewiring formed on the first insulating layer and connected to the pad via the first opening and second opening.

2. The semiconductor device according to claim 1, wherein the first bulge member is made of metal.

3. The semiconductor device according to claim 2, wherein the first bulge member is formed using metal paste.

4. The semiconductor device according to claim 1, wherein the first bulge member is formed in the periphery of the passivation film.

5. The semiconductor device according to claim 1, further comprising:
a second insulating layer formed on the first insulating layer and the rewiring, the second insulating layer being provided with a third opening positioned on the rewiring; and
a connecting terminal embedded in the third opening and connected to the rewiring.

6. The semiconductor device according to claim 5, wherein the connecting terminal is a solder ball.

7. The semiconductor device according to claim 5, further comprising:
a second bulge member formed on the first insulating layer and covered with the second insulating layer.

8. The semiconductor device according to claim 7, wherein the second bulge member is made of the same material as the rewiring.

9. A semiconductor device, comprising: an insulating film formed above a semiconductor substrate;
a pad formed on the insulating film;
a passivation film formed on the insulating film and the pad, the passivation film being provided with a first opening positioned on the pad;
a first insulating layer formed on the passivation film, the first insulating layer being provided with a second opening positioned on the first opening;
rewiring formed on the first insulating layer and connected to the pad via the first opening and second opening;
a bulge member formed on the first insulating layer; and
a second insulating layer formed on the first insulating layer, the bulge member, and the rewiring.

10. A method of manufacturing a semiconductor device, comprising:
forming an insulating film above a semiconductor substrate;
forming a pad on the insulating film;
forming a passivation film on the insulating film and the pad;
providing a first opening to the passivation film, the first opening being positioned on the pad;
forming a first bulge member on the passivation film;
forming a first insulating layer on the passivation film and the first bulge member, the first insulating layer being provided with a second opening positioned on the first opening; and
forming rewiring connected to the pad via the first opening and the second opening on the first insulating layer.

11. The method according to claim 10, wherein the step of forming the first bulge member includes:
ejecting metal paste on the passivation film using an inkjet mechanism; and
calcining the metal paste ejected on the passivation film to form the first bulge member.

12. The method according to claim 10,
wherein the step of forming the rewiring includes:
forming a conductive layer on the first insulating layer; and
patterning the conductive layer to form the rewiring and a second bulge member,
comprising after the step of patterning the conductive layer to form the rewiring and the second bulge member:
forming a second insulating layer on the first insulating layer, the rewiring, and the second bulge member, the second insulating layer being provided with a third opening positioned on the rewiring; and
forming a connecting terminal in the third opening.

13. The method according to claim 10, comprising after the step of forming the rewiring:
forming a second bulge member on the first insulating layer;
forming a second insulating layer on the first insulating layer, the rewiring, and the second bulge member, the second insulating layer being provided with a third opening positioned on the rewiring; and
forming a connecting terminal in the third opening.

14. A method of manufacturing a semiconductor device, comprising:
forming an insulating film above a semiconductor substrate;
forming a pad on the insulating film;
forming a passivation film on the insulating film and the pad;
providing a first opening to the passivation film, the first opening being positioned on the pad;
forming a first insulating layer on the passivation film, the first insulating layer being provided with a second opening positioned on the first opening;
forming, on the first insulating layer, rewiring connected to the pad via the first opening and the second opening and a bulge member;
forming a second insulating layer on the first insulating layer, the rewiring, and the bulge member, the second insulating layer being provided with a third opening positioned on the rewiring.
